(19) United States
(12) Patent Application Publication
(10) Pub. No.: US 2006/0131700 A1
(43) Pub. Date: Jun. 22, 2006

(54) Flexible electronic circuit articles and methods of making thereof

(76) Inventors: Moses M. David, Woodbury, MN (US); Catharine B. Shay, Maplewood, MN (US); Badri Veeraraghavan, Woodbury, MN (US); Hideo Yamazaki, Kanagawa (JP); James R. Shirck, Austin, TX (US)

Correspondence Address: 3M INNOVATIVE PROPERTIES COMPANY, PO BOX 33427, ST. PAUL, MN, 55133-3427, US

(21) Appl. No.: 11/021,135

(22) Filed: Dec. 22, 2004

(51) Int. Cl. H01L 23/58; H01L 21/469

(52) U.S. Cl. 257/632; 438/787; 438/789; 257/734

(57) ABSTRACT

The present invention includes an electronic-circuit article that has a substrate, a plasma deposited layer disposed on the substrate, where the plasma deposited layer comprises at least about 10.0 atomic percent, and a patterned conductive layer disposed above the plasma deposited layer.

### BACKGROUND

The present invention generally relates to flexible electronic circuit (FEC) articles and methods of making FEC articles. More particularly, the present invention relates to FEC articles that include plasma-deposited, silicon-containing layers.

FEC articles are used in a variety of commercial applications, such as circuits for inkjet cartridges, interconnects for integrated-circuit packaging, hard-disk drive circuits, and driver interconnections for liquid crystal displays. To function adequately in these applications, FEC articles generally require fine pitches (i.e., narrow widths) and good interlayer adhesion. Good interlayer adhesion is required to prevent interlayer delamination, especially when the FEC articles are exposed to high temperatures over time.

Conventional techniques for forming FEC articles typically involve depositing layers of conductive material on flexible substrates and patterning the deposited layers to create circuit traces. Examples of such deposition techniques include adhesive-based lamination, casting, and sputtering. Nonetheless, there exists a need for FEC articles that exhibit fine pitch, good interlayer adhesion, and good stability upon, and following, heating.

### BRIEF SUMMARY

At least one aspect of the present invention is directed to an electronic-circuit article that includes a substrate, a plasma deposited layer disposed on the substrate, and a patterned conductive layer disposed above the plasma deposited layer. The plasma deposited layer may comprises at least about 10.0 atomic percent At least one aspect of the present invention is further directed to an electronic-circuit article that includes a polyimide substrate, a plasma deposited layer disposed on the polyimide substrate, and a patterned conductive layer disposed above the plasma deposited layer. The plasma deposited layer may be derived from a gas comprising at least about 50.0 atomic percent of an organosilicon compound.

At least one aspect of the present invention is further directed to a method of forming an electronic-circuit article. The method may include plasma-depositing a silicon-containing layer on a substrate, depositing a layer of conductive material above the silicon-containing layer, and patterning the layer of conductive material.

Unless otherwise explicitly stated, the following definitions apply herein:

“Above”, as used herein with reference to the patterned conductive layer being disposed above the plasma deposited layer, means any location relative a major surface of the plasma deposited layer that is opposite the substrate. This definition includes the patterned conductive layer being disposed on the plasma deposited layer, and also includes the patterned conductive layer being disposed such that one or more layers are located between the patterned conductive layer and the plasma deposited layer.

“Plasma”means a partially ionized gaseous or fluid state of matter containing reactive species which include electrons, ions, neutral molecules, free radicals, and other excited state atoms and molecules. Visible light and other radiation are typically emitted from the plasma as the species forming the plasma relax from various excited states to lower, or ground, states. The plasma usually appears as a colored cloud in a reaction chamber.

“Negative bias” means that an object (e.g., an electrode) has a negative electric potential with respect to some other matter (e.g., a plasma) in the vicinity of the object.

“Negative self bias” with respect to an electrode and a plasma, means a negative bias developed by application of power to the electrode that creates a plasma.

### BRIEF DESCRIPTION OF THE DRAWINGS

FIG. 1 is a sectional view of a first embodiment of a flexible electronic circuit article of the present invention.

FIG. 2 is a sectional view of a second embodiment of the flexible electronic circuit article of the present invention.

FIG. 3 is a sectional view of a third embodiment of the flexible electronic circuit article of the present invention.

FIG. 4 is a sectional view of a fourth embodiment of the flexible electronic circuit article of the present invention.

FIG. 5 is a sectional view of a fifth embodiment of the flexible electronic circuit article of the present invention.

FIG. 6 is a sectional view of a sixth embodiment of the flexible electronic circuit article of the present invention.

FIG. 7 is a sectional view of a seventh embodiment of the flexible electronic circuit article of the present invention.

FIG. 8 is a sectional side view of an eighth embodiment of the flexible electronic circuit article of the present invention.

FIG. 9 is a schematic side view of a system for manufacturing the flexible electronic circuit article of the present invention.

FIG. 10 is a schematic view of an alternative system for manufacturing the flexible electronic circuit article of the present invention.

While the above-identified drawing figures set forth several embodiments of the invention, other embodiments are also contemplated, as noted herein. In all cases, this disclosure presents the invention by way of representation and not limitation. It should be understood that numerous other modifications and embodiments can be devised by those skilled in the art, which fall within the scope and spirit of the principles of the invention. The figures may not be drawn to scale. Like reference numbers have been used throughout the figures to denote like parts.

### DETAILED DESCRIPTION

### Description of the Flexible Electronic Circuit Articles

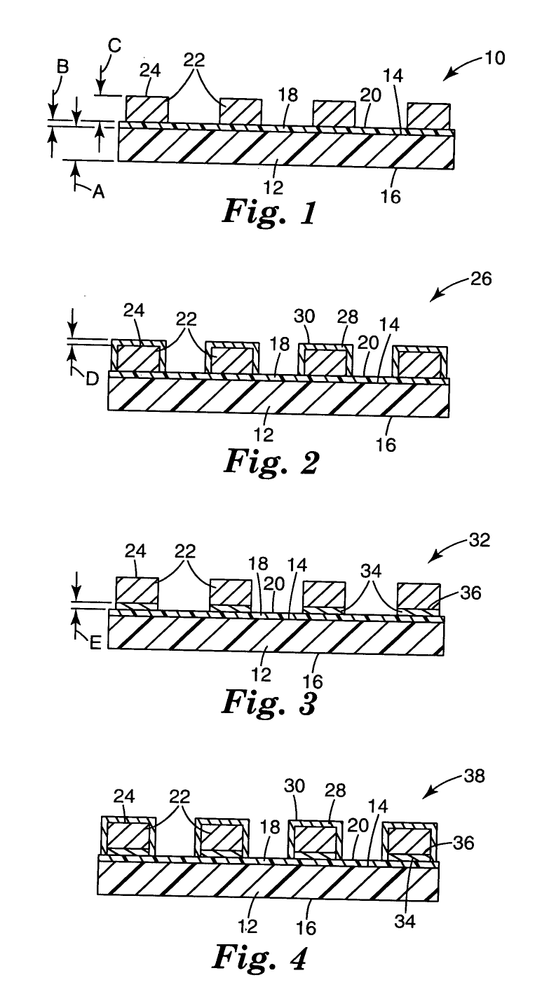

An aspect of the present invention is depicted sectionally in FIG. 1 as a FEC article 10, which is a multi-layered article formed by plasma deposition of gaseous organosilicon compounds and circuitization. As shown, the FEC article 10 includes a substrate 12 having a top surface 14 and a bottom surface 16. The gaseous organosilicon silicon compounds are plasma deposited on the top surface 14 of the substrate 12 to form a silicon-containing layer 18 having a top surface 20. A conductive trace layer 22 is then formed and patterned (i.e., circuitization) on the top surface 20 of the silicon-containing layer 18 to define an electrical circuit. In one embodiment, the silicon-containing layer 18 includes at least about 10.0 atomic percent silicon. This provides good interlayer adhesion between the substrate 12 and the conductive trace layer 22. The FEC article 10 also exhibits good environmental stability and is suitable for fine pitch applications.

The substrate 12 is a flexible polymeric film that is desirably formed from a material that is heat resistant and electrically insulating. Examples of suitable materials for the substrate 12 include polyimides, modified polyimides (e.g., polyester imides, poly-imide-esters, polysiloxane imides, and polyamide), polymethylmethacrylates, polyesters, polycarbonates, polytetrafluoroethylenes, polyphenylene sulfides, polyparabanates, polyesters, polyether sulfones, polyethylene naphthalates, polyether ether ketones, and combinations thereof. Examples of particularly suitable materials for the substrate 12 include polyimides, which exhibit good physical strengths, and are heat and chemical resistant. The substrate 12 may be extruded by conventional techniques to obtain a layer thickness A between the top surface 14 and the bottom surface 16. Examples of suitable layer thicknesses A for the substrate 12 range from about 12 micrometers to about 130 micrometers (about 0.5 mils to about 5 mils). However, the layer thickness A may vary as individual needs may require.

The silicon-containing layer 18 may be plasma deposited on the substrate 12 in a batch-wise process or a continuous process. A continuous process is desirably used to increase manufacturing efficiency. In general, plasma deposition involves moving a film of the substrate 12 through a chamber filled with one or more gaseous organosilicon compounds at a reduced pressure (relative to atmospheric pressure). Power is provided to an electrode (not shown) located adjacent to, or in contact with, the bottom surface 16 of the substrate 12. This creates an electric field, which forms a silicon-rich plasma from the gaseous organosilicon compound(s). Ionized molecules from the plasma then accelerate toward the electrode and impact on the top surface 14 of the substrate 12. By virtue of this impacting, the ionized molecules react with, and covalently bond to, the substrate 12. This creates the silicon-containing layer 18 on the substrate 12. One benefit of plasma deposition is the temperatures required for depositing the silicon-containing layer 18 are relatively low (e.g., about 10° C.). This is beneficial because high temperatures required for alternative deposition techniques (e.g., chemical vapor deposition) are known to degrade many materials suitable for the substrate 12, such as polyimides.

The extent of the plasma deposition may depend on a variety of processing factors, such as the composition of the gaseous organosilicon compound(s), the presence of other gases, the exposure time of the substrate 12 to the plasma, the level of power provided to the electrode, the gas flow rates, and the chamber pressure. These factors correspondingly help determine a layer thickness B of the silicon-containing layer 18. As depicted in FIG. 1, the layer thickness B extends from the top surface 14 of the substrate 12 to the top surface 20 of the silicon-containing layer 18. Examples of suitable layer thicknesses B for the silicon-containing layer 18 range from about 0.5 nanometers to about 10.0 nanometers. Examples of particularly suitable layer thicknesses B for the silicon-containing layer 18 range from about 1.0 nanometers to about 5.0 nanometers. These ranges of the layer thickness B help provide good interlayer adhesion between the substrate 12 and the conductive trace layer 22.

In addition to containing about 10.0% silicon, as discussed above, the silicon-containing layer 18 may also include at least about 15.0% by atomic percent oxygen,. Particularly suitable compositions for the silicon-containing layer 18 include one or more of the following: at least about 20.0 atomic percent silicon, at least about 25.0 atomic percent oxygen, and less than about 50.0 atomic percent carbon.

The conductive trace layer 22 is formed on the surface 20 of the silicon-containing layer 18 by depositing conductive material and patterning the deposited conductive material. Deposition of the conductive material may be performed by conventional deposition techniques, such as sputtering, vapor deposition, vacuum deposition, electroless plating, and electrolytic plating. Examples of suitable conductive materials include conductive metals such as tin, gold, silver, copper, chromium, and combinations thereof. Patterning may be performed by conventional photolithographic techniques to form the conductive trace layer 22 with a layer thickness C between the top surface 20 of the silicon-containing layer 18 and a top surface 24 of the conductive trace layer 22. Examples of suitable layer thicknesses C range from about 12 micrometers to about 130 micrometers (about 0.5 mils to about 5 mils). However, the layer thickness C may vary as individual needs may require.

Accordingly, after manufacture, the FEC article 10 of the present invention is a flexible circuit that includes an electrical circuit (i.e., the conductive trace layer 22) disposed on an electrically-insulating backing (i.e., the combination of the substrate 12 and the silicon-containing layer 18). The FEC article 10 exhibits good interlayer adhesion between the substrate 12 and the conductive trace layer 22, exhibits good stability, and is suitable for use with fine-pitch applications. Some materials suitable for the conductive trace layer 22 (e.g., copper) are known to degrade polyolefins suitable for the substrate 12, such as polyimides. As such, the silicon-containing layer 18 prevents the materials of the conductive trace layer 22 from interacting with the substrate 12.

FIG. 2 is a sectional view depicting an alternative FEC article of the present invention, referred to as a FEC article 26, which is similar to the FEC article 10, discussed above. However, the FEC article 26 additionally includes a plated layer 28 disposed on the conductive trace layer 22 to protect the conductive trace layer 22 from environmental conditions (e.g., corrosion). The FEC article 26 may be formed in the same manner as the FEC article 10. However, after the conductive trace layer 22 is deposited and patterned, additional conductive material (not shown) may be deposited on the top surface 20 of the silicon-containing layer 18 and the top surface 24 and sides of the conductive trace layer 22 by conventional deposition techniques (e.g., electroless plating and electrolytic plating). The additional conductive material may then be patterned with conventional photolithographic techniques to form the plated layer 28 with a layer thickness D between the top surface 24 of the conductive trace layer 22 and a top surface 30 of the plated layer 28. Examples of suitable layer thicknesses D range from about 2 micrometers to about 25 micrometers (about 0.1 mils to about 1 mil). However, the layer thickness D may also vary as individual needs may require.

Suitable materials for the plated layer 28 include the same materials as disclosed for the conductive trace layer 22. Accordingly, multiple deposition and patterning steps may be used to manufacture a plurality of conductive trace layers (e.g., the conductive trace layers 22 and 28) for the FEC articles of the present invention. The extent of the deposition and patterning steps may vary as individual needs may require.

FIG. 3 is a sectional view depicting another alternative FEC article of the present invention, referred to as a FEC article 32, which is similar to the FEC article 10, discussed above in FIG. 1. However, the FEC article 32 additionally includes a tie layer 34 disposed between the silicon-containing layer 18 and the conductive trace layer 22. The tie layer 34 provides additional adhesion for reducing potential interlayer delamination between the substrate 12 and the conductive trace layer 22. The tie layer 34 is particularly suitable when the conductive trace layer 22 is derived from materials (e.g., copper) that generally exhibit lower interlayer adhesion to polymeric substrates.

The substrate 12 and the silicon-containing layer 18 of the FEC article 32 are formed in the same manner as discussed above for the FEC article 10. However, after the silicon-containing layer 18 is plasma deposited, material for the tie layer 34 may be deposited on the surface 20 of the silicon-containing layer 18 by conventional deposition techniques, such as sputtering, vapor deposition, and vacuum deposition. Examples of suitable materials for the tie layer 34 include metals and metal alloys, such as chromium, nickel, nickel-chromium, oxides thereof, alloys thereof, and combinations thereof.

After material for the tie layer 34 is deposited, material for the conductive trace layer 22 may be deposited on the tie layer 34 using the techniques discussed above for the FEC article 10. The combined layers of material (of the conductive trace layer 22 and the tie layer 34 ) may then be patterned by conventional photolithographic techniques to form the conductive trace layer 22 and the tie layer 34, as depicted in FIG. 3. As shown, the tie layer 34 has a layer thickness E between the top surface 20 of the silicon-containing layer 18 and a top surface 36 of the tie layer 34. Examples of suitable layer thicknesses E range from about 2 micrometers to about 25 micrometers (about 0.1 mils to about 1 mil). However, the layer thickness E may also vary as individual needs may require.

FIG. 4 is a sectional view depicting another alternative FEC article of the present invention, referred to as a FEC article 38. The FEC article 38 combines some of the features of the FEC article 26 with some of the features of the FEC article 32, which are discussed above in relation to FIGS. 2 and 3. As shown in FIG. 4, the FEC article 38 includes the plated layer 28 disposed on the conductive trace layer 22, and the tie layer 34 disposed between the silicon-containing layer 18 and the conductive trace layer 22. The FEC article 38 may be generally formed in the same manner as discussed above for the FEC article 32 of FIG. 3. However, after the material for the conductive trace layer 22 and the tie layer 34 are deposited and patterned, material for the plated layer 28 may be deposited and patterned, as discussed above for the FEC article 26 of FIG. 2. The FEC article 38 provides the combined benefits of the tie layer 34 with the use of multiple conductive trace layers (i.e., the conductive trace layers 22 and 28 ).

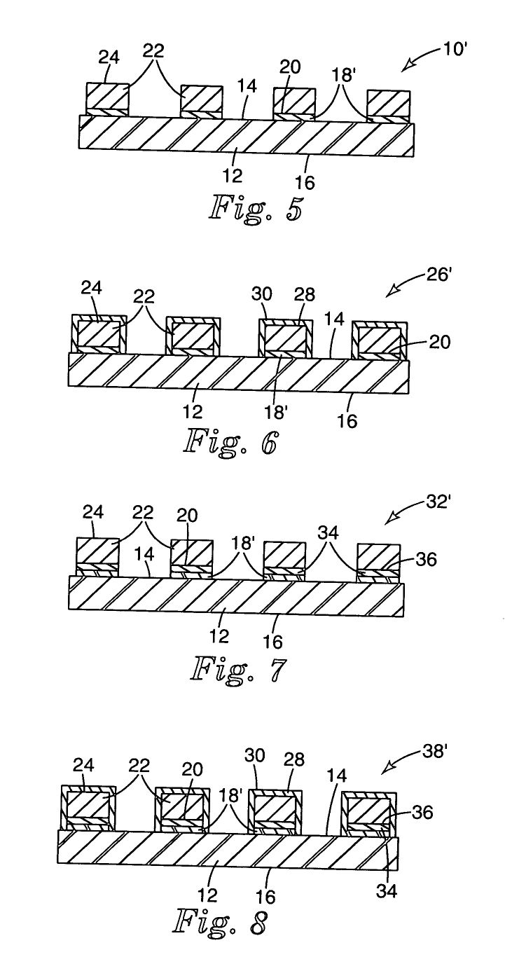

FIGS. 5-8 are sectional views depicting additional alternative FEC articles of the present invention (depicted as FEC articles 10′, 26′, 32 ′, and 38′), which are similar to those disclosed in FIGS. 1-4 (FEC articles 10, 26, 32, and 38, respectively). However, in FEC articles 10′, 26′, 32′, and 38′, the silicon-containing layer 18 (depicted as a silicon-containing layer 18′) is patterned along with the conductive trace layer 22 and/or the tie layer 34. This exposes the top surface 14 of the substrate 12 to the atmosphere, and provides increased flexibility in the FEC articles of the present invention. This increased flexibility correspondingly increases the versatility of the FEC articles of the present invention for use in a variety of different industrial applications.

As discussed above, the FEC articles of the present invention exhibit good interlayer adhesion and good stability upon, and following, heating. Examples of suitable characteristics for the FEC articles of the present invention include initial peel strengths of at least about 1.6 kilograms/centimeter (kg/cm) (about 3.0 pounds/inch), peel strengths after exposure to a temperature of 250° C. for one hour of at least about 1.1 kg/cm (about 2.0 pounds/inch), peels strengths after exposure to a temperature of 150° C. for 200 hours of at least about 1.1 kg/cm (about 2.0 pounds/inch), and insulation resistances of at least 10¹² ohms/100 millimeter². Examples of particularly suitable characteristics for the FEC articles of the present invention include initial peel strengths of at least about 2.1 kilograms/centimeter (kg/cm) (about 4.0 pounds/inch), peel strengths after exposure to a temperature of 250° C. for one hour of at least about 1.6 kg/cm (about 3.0 pounds/inch), peels strengths after exposure to a temperature of 150° C. for 200 hours of at least about 1.6 kg/cm (about 3.0 pounds/inch), and insulation resistances of at least 10¹³ ohms/100 millimeter². The peel strengths of the FEC articles of the present invention refer to the peel strengths between the substrate 12 and the conductive trace layer 22. Accordingly, the FEC articles of the present invention are capable of withstanding significant degrees of environmental exposure, which increase the versatility of the FEC articles of the present invention.

### Description of the Plasma Deposition Process

FIG. 9 is schematic side view depicting a system 40, which is a suitable system for plasma depositing the silicon-containing layer 18 on the substrate 12 in a continuous process. As previously discussed, the FEC articles of the present invention (e.g., FEC articles 10, 26, 32, 38, 10′, 26′, 32′, and 38′) are manufactured via plasma deposition. In this regard, the system 40 includes walls 42 that define a chamber 44, although the system 40 may be any apparatus capable of providing a controlled environment. For example, the chamber 44 is desirably capable of evacuation, containment of gases introduced after evacuation, plasma creation from the gaseous organosilicon compounds, ion acceleration, and supporting film deposition. Aluminum is a preferred material for the walls 42 because aluminum exhibits a low sputter yield, which correspondingly reduces contamination from the walls 42. However, other examples of suitable materials for the walls 42 include graphite, copper, glass, stainless steel, and combinations thereof.

Within the chamber 44, the system 40 may include a drum electrode 46, a plurality of reel mechanisms 48, a source spool 50, and a receiving spool 52. Suitable systems with these components are disclosed in David et al., U.S. Pat. No. 5,888,594 (“the '594 patent”) and U.S. Pat No. 5,948,166 (“the '166 patent”), and Yang et al., U.S. Pat. No. 6,071,597 (“the '597 patent”), all of which are incorporated by reference in their entireties. As disclosed in the '594 patent, the '166 patent, and the '597 patent, the substrate 12 may be fed from the source spool 50 as a film to the drum electrode 46, where the plasma deposition occurs. The resulting film (containing the substrate 12 and the silicon-containing layer 18) is then wound up on the receiving spool 52. The reel mechanisms 48 direct a line path of the film and provide tension to the film.

In addition to the components disclosed in the '594 patent, the '166 patent, and the '597 patent, the system 40 may also include a drying unit 54 to remove moisture from the substrate 12. The drying unit 54 may be any system suitable for drying the substrate 12. Prior to the plasma deposition, the substrate 12 may pass the drying unit 54 to reduce the moisture concentration in the substrate 12. Excessive moisture in the substrate 12 may reduce the effectiveness of the plasma deposition. An example of the drying unit 54 includes infrared lamps that direct infrared radiation toward the film (denoted by rays 54a).

As discussed above, suitable systems for the drum electrode 46 are disclosed in the '594 patent, the '166 patent, and the '597 patent. During operation, and prior to plasma deposition, the system 40 may be evacuated to remove air from the chamber 44, such as by means of vacuum pumps (not shown) connected to the chamber 44. After the air is purged from the chamber 44, the gaseous organosilicon compound(s) may then be introduced into the chamber 44 at a desired flow rate. The desired flow rate may depend on several factors, such as the size of the chamber 44 and the size of the substrate 12 surface area that will receive the deposited ions. Such flow rates are desirably sufficient to establish a suitable pressure, which typically ranges from about 1.0×10⁻⁶ Torr to about 1.0 Torr, for accomplishing the plasma deposition.

The gaseous organosilicon compound(s) used for the plasma deposition include any organosilicon compound(s) in a gaseous state at the reduced pressures of the chamber 44. Examples of suitable organosilicon compounds include trimethylsilane, triethylsilane, trimethoxysilane, triethoxysilane, tetramethylsilane, tetraethylsilane, tetramethoxysilane, tetraethoxysilane, hexamethylcyclotrisiloxane, tetramethylcyclotetrasiloxane, tetraethylcyclotetrasiloxane, octamethylcyclotetrasiloxane, hexamethyldisiloxane, bistrimethylsilylmethane, and combinations thereof. An example of a particularly suitable organosilicon compound includes tetramethylsilane. Furthermore, the gas may comprise silane.

In addition to the gaseous organosilicon compound(s), one or more gaseous non-organic compounds may also be introduced into the chamber 44 to assist the plasma deposition. Examples of suitable gaseous non-organic compounds include oxygen, argon, hydrogen, nitrogen, helium, ammonia, and combinations thereof. The flow rate of the gaseous non-organic compound(s) may vary depending on the desired ratio of gaseous non-organic compound(s) to gaseous organosilicon compound(s). However, the total flow rates of the gaseous non-organic compound(s) and the gaseous organosilicon compound(s) are desirably sufficient to establish a suitable pressure (e.g., from about 1.0×10⁻⁶ Torr to about 1.0 Torr) for accomplishing the plasma deposition.

Examples of suitable volumetric flow ratios of the gaseous non-organic compounds to the gaseous organosilicon compound(s) range from about 0:1 (i.e., no gaseous non-organic compound(s)) to about 10:1. The gaseous organosilicon compound(s) and the gaseous non-organic compound(s) may be introduced to the chamber 44 as a single premixed gas, or alternatively, as separate gases that substantially mix with each other within the chamber 44. For example, the gaseous organosilicon compound(s) may be introduced to the chamber 44 at a gas flow rate of about 80 standard cubic centimeters per minute (sccm) and the gaseous non-organic compound(s) may be introduced to the chamber 44 at a gas flow rate of about 320 sccm (i.e., a volumetric flow ratio of about 4:1).

As discussed in the '594 patent, the '166 patent, and the '597 patent, the drum electrode 46 may be a cylindrical electrode having an annular surface 56 made of any electrically conductive material. Examples of suitable materials for the annular surface 56 include aluminum, copper, steel, stainless steel, silver, chromium, alloys thereof, and combinations thereof. An example of a particularly suitable material for the annular surface 56 includes aluminum, due to the ease of fabrication, low sputter yield, and low costs associated with aluminum. The annular surface 56 allows an electric field to permeate radially outward from the drum electrode 46. The drum electrode 46 may also include non-conductive, insulative regions that prevent electric field permeation. Thus, plasma deposition is limited to the annular surface 56 of the drum electrode 46. The electrically non-conductive regions may be formed using any suitable electrically-insulating material, such as a polymer (e.g., polytetrafluoroethylene). Suitable widths of the annular surface 56 (in a direction perpendicular to a plane that is parallel to the view of FIG. 9) should generally be at least equal to the widths of the films to be coated (e.g., about 16.5 centimeters).

The drum electrode 46 also preferably includes a temperature control system 58 for supplying temperature controlling fluid to the drum electrode 46. The temperature control system 58 may heat or cool the drum electrode 46 as needed so the drum electrode 46 has an appropriate temperature that supports plasma deposition. In a preferred embodiment, the temperature control system 58 is a coolant system using a coolant fluid. Examples of suitable coolant fluids include water, ethylene glycol, chlorofluorocarbons, hydrofluoroethers, liquefied gases (e.g., liquid nitrogen), and combinations thereof.

Preferably, the temperature control system 58 pumps the coolant fluid (not shown) through the drum electrode 46 throughout the duration of the plasma deposition process to selectively control the drum electrode 46 temperature. Suitable temperatures for the drum electrode 46 range from about 5° C. to about 20° C. Since the substrate 12 is in direct contact with the drum electrode 46, heat transfer from the plasma to the substrate 12 is managed by this cooling approach and thereby allows plasma deposition on temperature sensitive films.

The drum electrode 46 also includes a power source 60 electrically connected to the drum electrode 46. The power source 60 may be provided on the system 40 or alternatively may be provided on a separate system and electrically connected to the drum electrode 46. In any case, the power source 60 may be any power generation or transmission system capable of supplying sufficient power to the drum electrode 46.

An example of a suitable power source 60 includes a radio frequency (RF) power source for supplying RF power. RF power exhibits a frequency that is high enough to form a negative bias on an appropriately configured version of the drum electrode 46, but not high enough to create standing waves in the resulting plasma. Standing waves generally decrease plasma deposition efficiency. RF power is scalable for high coating output (e.g., wide films and rapid line speeds). When RF power is used, the negative bias on the drum electrode 46 is a negative self bias (i.e., no separate power source need be used to induce the negative bias on the drum electrode 46).

The power source 60, as an RF power source, may power the drum electrode 46 with frequencies ranging from about 0.01 to about 50 MHz, preferably 13.56 MHz or any whole number (e.g., 1, 2, or 3) multiple thereof. This RF power, as supplied to the drum electrode 46, creates a silicon-rich plasma from the gaseous organosilicon compound(s) within the chamber 44. A suitable RF example of the power source 60 includes an RF generator, such as a 13.56 MHz oscillator connected to the drum electrode 46 via a network that functions to match the impedance of the power supply with that of the transmission line (which is usually 50 ohms resistive) and thereby effectively transmits RF power through a coaxial transmission line.

Upon application of RF power to the drum electrode 46, an ion sheath is formed, which causes the drum electrode 46 to become negatively self biased relative to the plasma. The ion sheath is necessary to obtain and support ion bombardment, which, in turn, is necessary to produce a densely packed silicon-containing layer 18 on the substrate 12. This negative self bias is generally in the range of 500 to 1400 volts, and causes the gaseous organosilicon compound(s) ionize and form a silicon-rich plasma with ions therein. Once the plasma has been created, a negative DC bias voltage is created on the drum electrode 46 by continuously powering the drum electrode 46 with RF power from the power source 60. This negative bias causes ions within the silicon-rich plasma to accelerate toward the non-insulated portion of the drum electrode 46 (i.e., the annular surface 56). The generation of the silicon-rich plasma also generally increases the pressure in the chamber 44. For example, a pre-plasma pressure of about 5.0×10⁻⁶ Torr within the chamber 44 may increase to about 5-10 milliTorr during plasma generation.

During formation of FEC articles of the present invention, the substrate 12, after drying, is fed around the annular surface 56 of the drum electrode 46 such that the bottom surface 16 of the substrate 12 contacts the annular surface 56. Accordingly, the ions of the plasma bombard the top surface 14 of the substrate 12 in contact with the drum electrode 46. This causes covalent bonding of the ionized silicon-containing compounds with the top surface 14, and consequent deposition of the silicon-containing layer 18 on the substrate 12 to form a film 63.

The resulting film 62 may then be wound up onto the receiving spool 52 for subsequent deposition and patterning of the conductive trace layer 22, the plated layer 28, and/or the tie layer 34. Alternatively, material for the conductive trace layer 22, the plated layer 28, and/or the tie layer 34 may be deposited as the resulting film 62 leaves the drum electrode 46 in a continuous process. The continuous process of the system 40 is advantageous because it allows material to be deposited on the top surface 20 of the silicon-containing layer 18 before the ions of the plasma stabilize. This increases the adhesion of the deposited material to the silicon-containing layer 18, which correspondingly increases interlayer adhesion of the resulting FEC article.

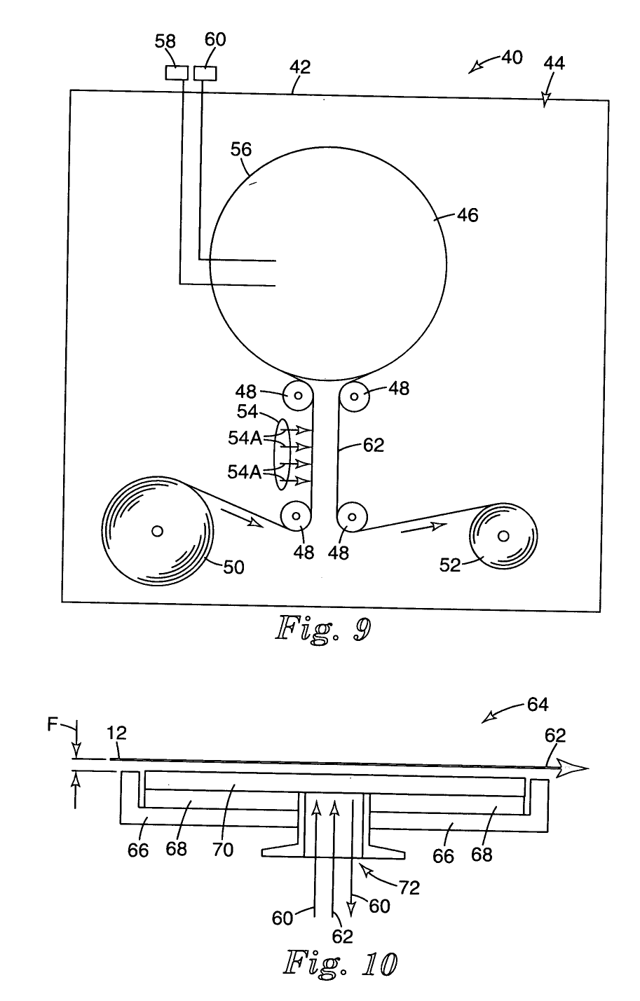

FIG. 10 is schematic side view of a planar electrode 64, which is an alternative 5 electrode apparatus to the drum electrode 46, and may replace the drum electrode 46 in the system 40. Examples of suitable systems for the planar electrode 64 are disclosed in David et al., U.S. Pat. No. 6,696,157, which is incorporated by reference in its entirety. As shown in FIG. 10, the planar electrode 64 includes a backing plate 66 and an insulating layer 68, which electrically insulate a conductive plate 70. Also included in the planar electrode 64 is a conduit 72 for supplying a coolant fluid from the temperature control system 58 and power from the power source 60 to the planar electrode 64. The temperature control system 58 and the power source 60 are each discussed above in FIG. 9, where the temperature control system 58 manages the temperature of the planar electrode 64 and the power source 60 supplies power to conductive plate 70.

During formation of FEC articles of the present invention, after drying at the drying unit 54, the substrate 12 may be fed across the conductive plate 70 of the planar electrode 64 with the bottom surface 16 of the substrate 12 disposed above the conductive plate 70 by a separation distance F. Examples of suitable separation distances F between the substrate 12 and the conductive plate 70 range from about 2.5 millimeters to about 13 millimeters. The separation distance F provides a non-contact arrangement between the substrate 12 and the conductive plate 70, in contrast to the annular surface 56 of the drum electrode 46, which contacts the bottom surface 16 of the substrate 12. Because of the planar nature and non-contact arrangement, the planar electrode 64 is efficient for forming FEC articles of the present invention with a continuous process. Alternatively, the bottom surface 16 of the substrate 12 may contact the conductive plate 70 as the substrate 12 is fed past the planar electrode 64.

Upon application of RF power to the conductive plate 70, an ion sheath is formed, which causes the conductive plate 70 to become negatively self biased relative to the plasma in the chamber 44, as discussed above. As discussed above, the ion sheath is necessary to obtain and support ion bombardment, which, in turn, is necessary to produce a densely packed silicon-containing layer 18 on the substrate 12. This bias is also generally in the range of 500 to 1400 volts, and causes the gaseous organosilicon compound(s) to become ionized, resulting in the formation of a silicon-rich plasma with ions therein. Once the plasma has been created, a negative DC bias voltage is created on the conductive plate 70 by continuously powering the conductive plate 70 with RF power from the power source 60. This bias causes ions within the silicon-rich plasma to accelerate toward the conductive plate 70. Accordingly, the ions bombard the top surface 14 of the substrate 12 disposed above the conductive plate 70. This causes covalent bonding of silicon-containing compounds with the top surface 14, and consequent deposition of the silicon-containing layer 18 on the substrate 12.

As with the drum electrode 46, the resulting film 62 from the planar electrode 64 may then be wound onto the receiving spool 52 (not shown in FIG. 10) for subsequent deposition and patterning of the conductive trace layer 22, the plated layer 28, and/or the tie layer 34. Alternatively, the conductive trace layer 22, the plated layer 28, and/or the tie layer 34 may be deposited as the resulting film 62 leaves the planar electrode 64 in a continuous process. This is particularly useful because of the planar, non-contact nature of the planar electrode 64.

Another suitable configuration for the system 40 may include both the drum electrode 46 and the planar electrode 64 within the same chamber 44. This allows the drum electrode 46 and the planar electrode 64 to each use the same reel mechanisms 48, source spool 50, and receiving spool 52, and thereby reduces apparatus costs. In use, either the drum electrode 46 or the planar electrode 64 may be used for plasma deposition, while the other electrode of the two remains unused. Additionally, devices for depositing the conductive trace layer 22, the plated layer 28, and/or the tie layer 34 may also be located within the chamber 44 to allow the layers of the FEC articles of the present invention to be deposited in a continuous process.

Overall, plasma generation and ion acceleration with the drum electrode 46 and the planar electrode 64 are greatly simplified. Only one electrode is used rather than a source electrode and a target electrode. The powered electrode both creates the plasma and becomes negatively self biased, thereby accelerating ions within the plasma toward the powered electrode for bombardment of the substrate 12. This DC biasing voltage also serves to densify the deposited coating, which enhances the properties of the silicon-containing layer 18.

### Description of the Conductive Layer Deposition Process and the Circuitization Process

After the silicon-containing layer 18 is plasma deposited on the substrate 12, additional material may be deposited on the resulting film 62 and patterned to form the conductive trace layer 22, the plated layer 28, and/or the tie layer 34. This provides the conductive portions of the FEC articles of the present invention, which function as electric circuits. As discussed above, the conductive trace layer 22, the plated layer 28, and/or the tie layer 34 may each- be deposited and patterned using a series of deposition and photolithography techniques, such as sputtering, electrolytic plating, resist exposing, resist developing, and etching. The sequence of such techniques may be varied as desired for particular applications. Examples of suitable techniques are disclosed in the '597 patent.

For FEC articles of the present invention that include the tie layer 34 (e.g., the FEC articles 32, 38, 32′, and 38′), material for the tie layer 34 is deposited on the top surface 20 of the silicon-containing layer 18. As discussed above, this may occur in a continuous process before the ions in the silicon-containing layer 18 stabilize, which increases adhesion of the tie layer 34 to the silicon-containing layer 18. As further discussed above, the tie layer 34 may be deposited by conventional deposition techniques, such as sputtering, vapor deposition, and vacuum deposition. For example, in one embodiment, material of the tie layer 34 may be magnetron sputtered onto the top surface 20 of the silicon-containing layer 18 with a direct current (DC) magnetron power setting of about 700 Watts. The sputtering may take place in a chamber that contains argon gas at a pre-sputtering pressure less than about 5.0×10⁻⁶ Torr (the sputtering process generally increases the pressure in the chamber). The chamber may be the chamber 40, as discussed above, which allows a continuous process to manufacture the FEC articles, or portions thereof, of the present invention. Alternatively, the chamber for sputtering the tie layer 34 may be separate from the chamber 40.

After the tie layer 34 is deposited, material for the conductive trace layer 22 is deposited on the surface 36 of the tie layer 34. As discussed above, the tie layer 34 may be deposited by conventional deposition techniques, such as sputtering, vapor deposition, vacuum deposition, and electrolytic plating. For example, in one embodiment, material for the conductive trace layer 22 may be deposited in a two-step process that involves depositing a seed layer followed by electrolytic plating. The seed layer is typically the same material used for the bulk of the conductive trace layer 22. The seed layer of the material for the conductive trace layer 22 may be magnetron sputtered onto the top surface 36 of the tie layer 34 with a DC magnetron power setting of about 2000 Watts. The sputtering may take place in a chamber that contains argon gas at a pre-sputtering pressure less than about 5.0×10⁻⁶ Torr (the sputtering process generally increases the pressure in the chamber).

The chamber for sputtering the seed layer may be the chamber 40, as discussed above, which allows a continuous process to manufacture the FEC articles, or portions thereof, of the present invention. The chamber for sputtering the seed layer may also be the same chamber as the chamber for sputtering the tie layer 34. This allows material for the tie layer 34 and the seed layer of the conductive trace layer 22 to be deposited sequentially in a continuous process (but separate from the plasma deposition). Alternatively, the chamber for sputtering the seed layer may be separate from the chamber 40 and from the chamber for sputtering the tie layer 34.

After the seed layer of the conductive trace layer 22 is deposited, the resulting film may be exposed to a series of baths to prepare the seed layer for electrolytic plating. For example, the resulting film may initially be placed in a solution comprising 75% (by volume) deionized (DI) water and 25% (by volume) of an aqueous composition comprising 15% by weight sulfonic acid and 15% sodium salt, which is commercially available from Learonal Inc., Freeport, N.Y., under the trade designation RONACLEAN PC-960M. This solution removes oxides and organic residue from the exposed surface of the seed layer. The resulting film may then be placed in a 1% by weight sodium persulfate solution, commercially available from Learonal Inc. under the trade designation RONAETCH. Finally, the resulting film may be placed in a 10% sulfuric acid (H₂SO₄) solution. The resulting film is then ready for electrolytic plating of the remaining portion of the conductive trace layer 22 on top of the seed layer.

Material for the remaining portion of the conductive trace layer 22 may be electrolytic plated using conventional electrolytic plating techniques. For example, in one embodiment, copper material for the conductive trace layer 22 may be plated on the seed layer by placing the resulting film in a solution comprising about 18% H₂SO₄ and about 23% CuSO₄*5H₂O. A current (e.g., about 200 amps/meter²) is applied to the solution to plate the seed layer. The current may be applied by any conventional power source, such as a power source available under the trade designated DYNATRONIX Model PMC 104/PR-20-60 Programmable Power Supply, commercially available from Dynatronix, Inc., Amery, Wis. Once the electrolytic plating is complete, the tie layer 34 and the conductive trace layer 22 are ready for patterning.

Patterning of the tie layer 34 and the conductive trace layer 22 may be performed by any variety of different photolithographic techniques. In one embodiment, photoresists, which may be aqueous or solvent based, and may be negative or positive photoresists, are laminated on the bottom surface 16 of the substrate 12 and the top surface 24 of the conductive trace layer 22. The photoresists may be applied using standard laminating techniques with hot rollers. Suitable thickness for the photoresists range from about 35 to about 50 micrometers. The photoresists may then be exposed on both sides to ultraviolet light or the like, through a mask or phototool. This crosslinks the portions of the photoresists that are not covered by the mask. Because the bottom surface 16 of the substrate 12 is not patterned, the photoresist applied to the bottom surface 16 is flood exposed. The unexposed portions of the photoresists are then developed with an appropriate solvent. In the case of aqueous resists, a dilute aqueous solution (e.g., a solution comprising about 0.5% to about 1.5% by weight sodium carbonate or potassium carbonate) may be applied until desired patterns are obtained on the top surface 24 of the conductive trace layer 22.

After the photoresist is formed, the film may then be sprayed with an etchant solution, which etches the portions of the conductive trace layer 22 not covered by the crosslinked photoresist. An example of a suitable enchant solution for etching the conductive trace layer 22 includes a solution comprising about 10.0% by weight H₂SO₄ and about 2.0% to about 3.0% by weight H₂O₂. The etching exposes certain areas of the top surface 34 of the tie layer 32 (i.e., the conductive trace layer 22 is patterned). The photoresists may be removed at this point or retained for subsequent etching, depending on the photolithographic techniques used.

After the conductive trace layer 22 is patterned, the tie layer 34 may then be etched by placing the resulting film in a second etchant solution, which etches the portions of the tie layer 34 not covered by the crosslinked photoresist. An example of a suitable enchant solution for etching the trace layer 34 includes a solution comprising about 4.0% by weight KOH and about 2.5% by weight KMnO₄. The resulting film may then be placed in a third solution comprising about 10.0% by weight H₂SO₄ for post-etching neutralization. When etching is completed, the photoresist may then be stripped from the top surface 24 of the conductive trace circuit 22 and the bottom surface 16 of the substrate 12. Other steps may also be included in the process, such as rinsing the film with deionized water before and/or after the etching steps, drying the film, and other conventional film cleaning steps. The resulting film may then be separated into separate FEC articles (e.g., the FEC articles 32, 38, 32′, and 38′) for use in a variety of industrial applications.

For FEC articles of the present invention that also include the conductive trace circuit 28 located on the conductive trace circuit 22 (e.g., the FEC articles 26, 38, 26′, and 38′), material for the conductive trace circuit 28 may be deposited and patterned in the same manner as discussed above for the conductive trace circuit 22. Material for the conductive trace circuit 28 may be deposited before or after the conductive trace circuit 22 is patterned. In one embodiment, material for the conductive trace circuit 28 is deposited before the conductive trace circuit 22 is patterned. In this case, the photoresist may be formed and crosslinked on the top surface 30 of the conductive trace circuit 28, rather than on the top surface 24 of the conductive trace circuit 22. The conductive trace circuit 28 may then be patterned along with the conductive trace circuit 22, as discussed above.

In another embodiment, the conductive trace circuit 22 and the tie layer 34 are patterned prior to forming the conductive trace circuit 28. This produces the FEC articles 26, 38, 26′, and 38′, as shown in FIGS. 2, 4, 6, and 8. In this case, after the conductive trace circuit 22 and the tie layer 34 are patterned, a seed layer of material for the conductive trace circuit 28 may be deposited, followed by electrolytic plating. Alternatively, if the materials of the conductive trace circuit 22 and the conductive trace circuit 28 provide adequate interlayer adhesion between the conductive trace circuit 22 and the conductive trace circuit 28, the seed layer may be not be required.

After deposition, the conductive trace circuit 28 may then be patterned in the same manner discussed above for the conductive trace circuit 22. Accordingly, a second photoresist may be formed and crosslinked on the top surface 30 of the conductive trace circuit 28. The resulting film may then be etched to define the circuit traces, and the photoresist may then be stripped, as discussed above.

The FEC articles of the present invention may also include additional conductive trace circuits beyond the conductive trace circuit 22 and the conductive trace circuit 28. The additional conductive trace circuits may be deposited and patterned in the same manners as discussed above for the conductive trace circuit 22 and the conductive trace circuit 28.

For FEC articles of the present invention that do not include the tie layer 34 (e.g., the FEC articles 10, 26, 10′, and 26′), the conductive trace layer 22 may be deposited on the top surface 20 of the silicon-containing layer 18 and patterned in the same manner as discussed above. For FEC articles of the present invention that include the patterned silicon-containing layer 18′ (e.g., the FEC articles 10′, 26′, 32′, and 38′), the silicon-containing layer 18′ may be etched along with the tie layer 34 and/or the conductive trace layer 22, following the same patterning steps discussed above.

After plasma deposition and circuitization, the FEC articles of the present invention have conductive circuitry on one side, and a polymeric substrate surface on the opposing side. The FEC articles may be connected to printed circuit boards or other devices by a variety of conventional means, such as solder balls, reflow solder, thermal compression bonding, wire bonding, inner lead bonding, and the like. Accordingly, the FEC articles of the present invention are useful in electronic packages such as ball grid arrays, chip scale packages, single and multiple metal layer packages and the like. Such circuits and packages can be designed for use in any electronic device, including but not limited to recording devices, printing devices, single or multimedia devices, projectors, cameras, computers, data storage devices, and the like.

### Property Analysis and Characterization Procedures

Various analytical techniques are available for manufacturing and characterizing the FEC articles of the present invention. Several of the techniques are employed herein. An explanation of these techniques follows.

### Drum Electrode Manufacturing Method

FEC articles of the present invention were manufactured by plasma deposition with a drum electrode, and subsequent circuitization, by the following procedure. A polyimide substrate film was provided on a source spool, where the substrate film exhibited a film layer thickness of 50.8 micrometers and a cross-sectional film width of 15.2 centimeters. The substrate film was initially fed to an IR lamp with a Variac autotransforner, Model 033-3504, which is commercially available from Staco Energy Products, Dayton, Ohio (60% power setting). The IR lamp was contained in a chamber having a pressure maintained at 1.0×10⁻⁶ Torr to remove moisture from the substrate film. The substrate film was fed at a line speed of 0.61 meters/minute.

Next, the substrate film was fed around an annular surface of a drum electrode, for plasma deposition. The drum electrode had a diameter of 50.8 centimeters (20.0 inches) and the annular surface had a 16.5-centimeter (6.5-inch) width. The drum electrode also included an O₂ glow discharge device containing a rod cathode and a tubular anode with cutout. Prior to the plasma deposition, the chamber was purged of air and a gas (the composition of the gas varied between the Examples) was then pumped into the chamber at a flow rate to provide a pre-plasma pressure maintained at 5.0×10⁻⁶ Torr. Circulating water maintained at 10° C. was also pumped through the drum electrode from a temperature control system. The drum electrode was then supplied with RF power of 2000 Watts to create a plasma in the gas. This increased the chamber pressure to about 4-7 milliTorr. The substrate film was then fed around the annular surface of the drum electrode at a line speed of 4.6 meters/minute, which created an exposure time to the plasma of three seconds. The exposure time was measured as the total amount of time that a given portion of the substrate film was in contact with the annular surface of the drum electrode and exposed to the plasma. Ions from the plasma were deposited on the top surface of the substrate film to form the silicon-containing layer. The resulting film was then wound onto a receiving spool.

A NiCr tie layer was deposited on the silicon-containing layer by feeding the film (containing the substrate and the silicon-containing layer) at a line speed of 4.6 meters/minute through a chamber. Prior to sputtering, the chamber was purged of air and then filled with argon at flow rate of 400 sccm to provide a pre-sputtering pressure of 5.0×10⁻⁶ Torr. The tie layer was deposited on the silicon-containing layer by magnetron sputtering a NiCr material with a DC magnetron power setting of 700 Watts. The sputtering process increased the pressure in the chamber to 7.0 milliTorr.

Next, a copper (Cu) seed layer was deposited on the tie layer by feeding the film (containing the substrate, the silicon-containing layer, and the NiCr tie layer) at a line speed of 4.6 meters/minute through a chamber. Prior to sputtering, the chamber was purged of air and then filled with argon at flow rate of 400 sccm to provide a pre-sputtering pressure of 5.0×10⁻⁶ Torr. The Cu seed layer was deposited on the NiCr tie layer by magnetron sputtering a copper material with a DC magnetron power setting of 2000 Watts. The sputtering process increased the pressure in the chamber to 7.0 milliTorr.

After the seed layer was deposited, the film was placed in a solution for 2 minutes at 25° C., where the solution comprised 75% (by volume) deionized (DI) water and 25% (by volume) of an aqueous composition comprising 15% by weight sulfonic acid and 15% sodium salt, which is commercially available from Learonal Inc. under the trade designation RONACLEAN PC-960M. The film was then sprayed for 2 minutes with DI water. Then film was then dipped into a RONAETCH copper bath, commercially available from Learonal Inc., which consisted of a 1.0% by weight sodium persulfate solution. The film was then sprayed again for 2 minutes with DI water. Finally, the sheet was dipped for 15 seconds into a 10% by weight H₂SO₄ bath. After the series of baths, the film was ready for electrolytic plating.

Electrolytic plating was performed by placing the film (containing the substrate, the silicon-containing layer, the NiCr tie layer, and the Cu seed layer) in a 22 gallon bath. The bath contained a solution that was air agitated, and also contained baskets with copper-phosphorous nuggets. The solution comprised 18% by weight H₂SO₄, 23% by weight CuSO₄*5H₂O, 2% by weight of a carrier/brightener solution commercially available as Copper Gleam CLX Additive from Rohm and Haas Electronic Materials Co., Marlborough, Mass., and 2% by weight PPR Carrier, commercially available from Rohm and Haas Electronic Materials Co. The bath was charged with a current density of 200 amps/meter² (20 amps/foot²) from a DYNATRONIX Model PMC 104/PR-20-60 Programmable Power Supply, commercially available from Dynatronix, Inc. The film resided in the bath for 43 minutes with a plating distance of 24.1-25.4 centimeters (9.5-10 inches). Upon removal from the bath, the film was ready for circuitization (i.e., patterning).

### Planar Electrode Manufacturing Method

FEC articles of the present invention were manufactured by plasma deposition with a planar electrode, and subsequent circuitization, by the following procedure. A polyimide substrate film was provided on a source spool, where the substrate film exhibited a film layer thickness of 50.8 micrometers and a cross-sectional film width of 15.2 centimeters. The substrate film was initially fed to an IR lamp with a Variac autotransformer, Model 033-3504, which is commercially available from Staco Energy Products, Dayton, Ohio (60% power setting). The IR lamp was contained in a chamber having a pressure maintained at 1.0×10⁻⁶ Torr to remove moisture from the substrate film. The substrate film was fed at a line speed of 0.61 meters/minute.

Next, the substrate film was fed past a planar electrode at a separation distance of 0.64 centimeters (0.25 inches), for plasma deposition. The planar electrode was installed in a Leybold production metallizer, commercially available from, Leybold Vacuum Products Inc., Export, Pa. The planar electrode included a conductive surface with a length (in the direction of movement of the substrate film) of 26.7 centimeters (10.5 inches) and a width of 38.1 centimeters (15.0 inches). Prior to the plasma deposition, the chamber was purged of air and a gas (the composition of the gas varies between the Examples) was then pumped into the chamber at a flow rate to provide a pre-plasma pressure maintained at 5.0×10⁻⁶ Torr. Circulating water maintained at 10° C. was also pumped through the planar electrode from a temperature control system. The planar electrode was then supplied with RF power of 2000 Watts to create a plasma in the gas. This increased the chamber pressure to 7.0 milliTorr. The substrate film was then fed past the planar electrode at a line speed of 4.6 meters/minute, which created an exposure time to the plasma of three seconds. The exposure time was measured as the total amount of time that a given portion of the substrate film passed over the conductive surface of the planar electrode and exposed to the plasma. Ions from the plasma were deposited on the top surface of the substrate film to form the silicon-containing layer.

After the plasma deposition, the film (containing the substrate and the silicon-containing layer) was fed past a sputtering device for depositing a NiCr tie layer in a continuous process, in the same chamber. The tie layer was deposited on the silicon-containing layer by magnetron sputtering a NiCr material with a DC magnetron power setting of 700 Watts. The film (containing the substrate, the silicon-containing layer, and the NiCr tie layer) was then fed past a second sputtering device for depositing a Cu seed layer on the tie layer in a continuous process, in the same chamber. The Cu seed layer was deposited on the NiCr tie layer by magnetron sputtering a copper material with a DC magnetron power setting of 2000 Watts. After the Cu seed layer was deposited, the film was wound onto a receiving spool for electrolytic plating.

Prior to the electrolytic plating, the film was placed in a solution for 2 minutes at 25° C., where the solution comprised 75% (by volume) deionized (DI) water and 25% (by volume) of an aqueous composition comprising 15% by weight sulfonic acid and 15% sodium salt, which is commercially available from Learonal Inc. under the trade designation RONACLEAN PC-960M. The film was then sprayed for 2 minutes with DI water. Then film was then dipped into a RONAETCH copper bath, commercially available from Learonal Inc., which consisted of a 1.0% by weight sodium persulfate solution. The film was then sprayed again for two minutes with DI water. Finally, the sheet was dipped for 15 seconds into a 10% by weight H₂SO₄ bath. After the series of baths, the film was ready for electrolytic plating.

Electrolytic plating was performed by placing the film (containing the substrate, the silicon-containing layer, the NiCr tie layer, and the Cu seed layer) in a 22 gallon bath. The bath contained a solution that was air agitated, and also contained baskets with copper-phosphorous nuggets. The solution comprised 18% by weight H₂SO₄, 23% by weight CuSO₄*5H₂O, 2% by weight of a carrier/brightener solution commercially available as Copper Gleam CLX Additive from Rohm and Haas Electronic Materials Co., Marlborough, Mass., and 2% by weight PPR Carrier, commercially available from Rohm and Haas Electronic Materials Co. The bath was charged with a current density of 200 amps/meter² (20 amps/foot²) from a DYNATRONIX Model PMC 104/PR-20-60 Programmable Power Supply, commercially available from Dynatronix, Inc. The film resided in the bath for 43 minutes with a plating distance of 24.1-25.4 centimeters (9.5-10 inches). Upon removal from the bath, the film was ready for circuitization (i.e., patterning).

### Circuitization Method

The films manufactured pursuant to the Drum Electrode Manufacturing Method and the Planar Electrode Manufacturing Method were patterned pursuant to the following procedure to form circuits. Photoresists were formed on the surface of the conductive layer and the bottom surface of the substrate with a trade designated XRL-120A Hot Roller Laminator, commercially available from Western Magnum, El Segundo, Calif. The film was fed past the laminator at a line speed of 45.7 centimeters/minute (1.5 feet/minute). The lamination temperature was 127° C. (260° F.) and the lamination pressure was 414 kilopascals (60 pounds/inch²). The photoresists contained a polyethylene liner, a poly(methyl methacrylate) photoresist layer, and a polyester coversheet, and are commercially available from MacDermid, Inc., Waterbury, Conn, under the trade designation Aqua-Mer SF320 Dry Film Photoresist. Prior to lamination, the polyethylene liner and the polyester coversheet were removed from the photoresist layer.

Next, the photoresist formed on the conductive layer was crosslinked by a 15 milliwatt/centimeter² UV radiation exposure through a mask for 15 seconds. The photoresist formed on the substrate was crosslinked by a flood exposure of the 15 milliwatt/centimeter² UV radiation for the 15 seconds. The UV radiation was provided by a trade designated JBA ultra-violet exposure system equipped with a 500-watt short arc mercury lamp, commercially available from JBA Associates, San Jose, Calif. The photoresists were the developed with a trade designated ASI model TT-24 spray developer, commercially available from Eidschun Engineering, Inc., Clearwater, Fla. The developing speed was 27.4 centimeters/minute (0.9 feet/minute), the developing temperature was 29.4° C. (85° F.), the developer bath comprised 0.85% by weight K₂CO₃, and the spray pressure was 172 kilopascals (25 pounds/inch²).

Next, the Cu layers were etched with the model TT-24 spray developer using an etch bath maintained at 43° C. (110° F.), with a spray pressure of 172 kilopascals (25 pounds/inch²), and a bath speed of 9.1 centimeters/minute (0.3 feet/minute). The bath comprised 10.0% by weight H₂SO₄ and 2.0%-3.0% by weight H₂O₂. After etching, the photoresist was removed with a solution maintained at 25° C. The solution comprises 50% DI water and 50% of a trade designated Resist Stripper S-8044i, commercially available from Toryon Technologies, Itasca, Ill.

Next, the FEC articles were cut individually from the film and checked for shorts with a multimeter. The FEC articles were then individually placed in a NiCr etch solution for two minutes to etch the NiCr tie layer. The NiCr etch solution was prepared by dissolving 4.0 grams of KOH and 2.5 grams of KMnO₄ in 100 milliliters of water, and heating to 57° C. (137° F.). After removal from the NiCr etch solution, the FEC articles were rinsed with DI water and placed in a 10.0% by weight H₂SO₄ solution for one minute to neutralize the NiCr etch solution. The FEC articles were rinsed again with DI water for one minute and blown dry with nitrogen gas.

### Initial Peel Strength Testing

The peel strengths (i.e., interlayer adhesion strengths) of the FEC articles were quantitatively measured pursuant to the following procedure after the FEC articles were manufactured. A sample of the FEC article was placed on a glass slide using SCOTCH Permanent Double Stick Tape, commercially available from 3M Corporation, St. Paul, Minn. Three traces of the sample were partially peeled up to 2-4 millimeters to initiate the peeling. The glass slide with the sample was mounted on an INSTRON Test Equipment, Model 55.67, which is commercially available from Instron Corporation, Canton, Mass. A clip is connected to a 10 gram load cell and to one of the traces of the sample. The sample was positioned so that the peel angle was 90+/−10 degrees. The peel strength of the conductive trace layer to the substrate was then measured with a crosshead speed of 1.27 centimeters/minute (0.5 inches/minute). The peel strength was recorded when the load weight became substantially constant. The test was repeated with the two remaining traces that were initially peeled. The tabulated results herein are the average of the three test runs.

### 250° C., 1 hr Peel Strength Testing

The peel strengths of the FEC articles were quantitatively measured pursuant to the Initial Peel Strength Testing, discussed above, after the FEC articles were manufactured and placed in a 250° C. oven for one hour. This tested the stability of the FEC articles after exposure to a high temperature.

### 150° C. 200 hr Peel Strength Testing

The peel strengths of the FEC articles were quantitatively measured pursuant to the Initial Peel Strength Testing, discussed above, after the FEC articles were manufactured and placed in a 150° C. oven for 200 hours. This tested the stability of the FEC articles after exposure to heat over an extended period of time.

### Solder Reflow Peel Strength Testing

The peel strengths of the FEC articles were quantitatively measured pursuant to the Initial Peel Strength Testing, discussed above, after the FEC articles were manufactured and placed in a solder reflow oven with a nitrogen gas ambient. Solder reflowing is a widely accepted method of attaching electronic components to a printed circuit board. As such, FEC articles of the present invention desirably exhibit good stability upon exposure to solder reflow conditions.

### Insulation Resistance Testing

The insulation resistance of the FEC articles were quantitatively measured with the following procedure. 50×50 millimeter square samples of each FEC article was created with thicknesses of two millimeters. A 100-volt DC voltage was induced across the traces at 25° C. and atmospheric pressure. The resulting current was measured with a picoammeter. The surface resistance was calculated from the voltage and the resulting currents. Sheet resistance (ohms/square) was calculated by dividing surface resistance by the product of the number of traces in the square of the FEC article and the aspect ratio.

The FEC articles of the present invention desirably retain good insulation resistance after plasma deposition. Low insulation resistance can be detrimental to the performance of the FEC articles due to leakage currents between the traces, especially in fine pitch applications.

### EXAMPLES

The present invention is more particularly described in the following examples that are intended as illustrations only, since numerous modifications and variations within the scope of the present invention will be apparent to those skilled in the art. Unless otherwise noted, all parts, percentages, and ratios reported in the following examples are on a atomic percent basis, and all reagents used in the examples were obtained, or are available, from the chemical suppliers described below, or may be synthesized by conventional techniques.

The following compositional abbreviations are used in the following Examples:
“Polyimide”: Polyimide film commercially available under the trade designation KAPTON E polyimide film from E. I. DuPont de Nemours Co., Wilmington, Del.
“TMS”: NMR-grade Tetramethylsilane (Si(CH₃)₄) commercially available from Sigma-Aldrich Chemical Company, Saint Louis, Mo.
“Argon”: Ultra-pure argon gas commercially available from Sigma-Aldrich Chemical Company.
“Oxygen”: Ultra-pure oxygen gas commercially available from Sigma-Aldrich Chemical Company.
“Nitrogen”: Ultra-pure nitrogen gas commercially available from Sigma-Aldrich Chemical Company.

### Examples 1-15 and Comparative Examples A-C

Examples 1-15 are FEC articles of the present invention that were prepared pursuant to the Drum Electrode Manufacturing Method and the Circuitization Method, as discussed above, with the exceptions that the RF power and the exposure times of the plasma deposition were varied as shown in Table 1. Table 1 provides the gas flow rates, RF power, and the exposure times used during plasma deposition for manufacturing the FEC articles of Examples 1-15.

TABLE 1

| | | | | Nitrogen | Exposure | |
|---|---|---|---|---|---|---|
| | TMS Flow | Argon Flow | Oxygen Flow | Flow Rate | Time | RF Power |
| Example | Rate (sccm) | Rate (sccm) | Rate (sccm) | (sccm) | (seconds) | (watts) |
| Example 1 | 180 | 170 | 0 | 0 | 4 | 1000 |
| Example 2 | 180 | 170 | 0 | 0 | 10 | 2000 |
| Example 3 | 180 | 170 | 0 | 0 | 4 | 1000 |
| Example 4 | 180 | 170 | 0 | 0 | 10 | 2000 |
| Example 5 | 180 | 0 | 200 | 0 | 4 | 2000 |
| Example 6 | 180 | 0 | 200 | 0 | 8 | 2000 |
| Example 7 | 180 | 100 | 100 | 0 | 4 | 2000 |
| Example 8 | 180 | 100 | 100 | 0 | 8 | 2000 |
| Example 9 | 180 | 0 | 0 | 0 | 4 | 2000 |
| Example 10 | 180 | 0 | 0 | 0 | 8 | 2000 |
| Example 11 | 180 | 170 | 0 | 0 | 4 | 1000 |
| Example 12 | 180 | 170 | 0 | 0 | 10 | 2000 |
| Example 13 | 180 | 170 | 0 | 0 | 18 | 2000 |
| Example 14 | 180 | 0 | 200 | 0 | 4 | 2000 |
| Example 15 | 180 | 0 | 0 | 170 | 20 | 2000 |

Comparative Example A was prepared pursuant to the Drum Electrode Manufacturing Method and the Circuitization Method, as discussed above, with the following exceptions. An oxygen glow discharge device was mounted adjacent the annular surface of the drum electrode, which provided oxygen to the chamber at a flow rate of 500 sccm (no TMS was present). The drum electrode was powered with 3000 volts and a current of 26 milliamps. This produced an operating pressure of five milliTorr. The polyimide substrate film was fed around the drum electrode at a speed of 61 centimeters/minute (two feet/minute).

The FEC articles of Examples 1-15 and Comparative Example A were tested pursuant to the Initial Peel Strength Testing, the 250° C., 1 hr Peel Strength Testing, and the 150° C., 200 hr Peel Strength Testing. Table 2 provides the peel strength results for the FEC articles of Examples 1-4 and Comparative Example A, Table 3 provides the peel strength results for the FEC articles of Examples 5-10 and Comparative Example A, and Table 4 provides the peel strength results for the FEC articles of Examples 11-15 and Comparative Example A.

TABLE 2

| | Peel Strength | Peel Strength | Peel Strength | Peel Strength | Peel Strength | Peel Strength |
|---|---|---|---|---|---|---|
| | (initial) | (initial) | (250° C., 1 hr.) | (250° C., 1 hr.) | (150° C., 200 hr.) | (150° C., 200 hr.) |
| Example | (grams/cm) | (lbs./in.) | (grams/cm) | (lbs./in.) | (grams/cm) | (lbs./in.) |
| Example 1 | 575 | 3.22 | 505 | 2.83 | 548 | 3.07 |
| Example 2 | 757 | 4.24 | 454 | 2.54 | 589 | 3.30 |
| Example 3 | 766 | 4.29 | 755 | 4.23 | 655 | 3.67 |
| Example 4 | 821 | 4.60 | 788 | 4.41 | 804 | 4.50 |
| Comparative | 779 | 4.36 | 234 | 1.31 | 246 | 1.38 |
| Example A | | | | | | |

TABLE 3

| | Peel Strength | Peel Strength | Peel Strength | Peel Strength | Peel Strength | Peel Strength |
|---|---|---|---|---|---|---|
| | (initial) | (initial) | (250° C., 1 hr.) | (250° C., 1 hr.) | (150° C., 200 hr.) | (150° C., 200 hr.) |
| Example | (grams/cm) | (lbs./in.) | (grams/cm) | (lbs./in.) | (grams/cm) | (lbs./in.) |
| Example 5 | 714 | 4.00 | 429 | 2.40 | 477 | 2.67 |
| Example 6 | 663 | 3.71 | 279 | 1.56 | 418 | 2.34 |
| Example 7 | 596 | 3.34 | 411 | 2.30 | 445 | 2.49 |
| Example 8 | 943 | 5.28 | 554 | 3.10 | 518 | 2.90 |
| Example 9 | 771 | 4.32 | 486 | 2.72 | 430 | 2.41 |
| Example 10 | 7.00 | 0.04 | 0.00 | 0.00 | 0.00 | 0.00 |
| Comparative | 779 | 4.36 | 234 | 1.31 | 214 | 1.20 |
| Example A | | | | | | |

TABLE 4

| | Peel Strength | Peel Strength | Peel Strength | Peel Strength | Peel Strength | Peel Strength |
|---|---|---|---|---|---|---|
| | (initial) | (initial) | (250° C., 1 hr.) | (250° C., 1 hr.) | (150° C., 200 hr.) | (150° C., 200 hr.) |
| Example | (grams/cm) | (lbs./in.) | (grams/cm) | (lbs./in.) | (grams/cm) | (lbs./in.) |
| Example 11 | 477 | 2.67 | 545 | 3.05 | 579 | 3.24 |
| Example 12 | 0.00 | 0.00 | 0.00 | 0.00 | 0.00 | 0.00 |
| Example 13 | 525 | 2.94 | 448 | 2.51 | 677 | 3.79 |
| Example 14 | 520 | 2.91 | 321 | 1.80 | 509 | 2.85 |
| Example 15 | 0.00 | 0.00 | 0.00 | 0.00 | 0.00 | 0.00 |
| Comparative | 779 | 4.36 | 234 | 1.31 | 214 | 1.20 |
| Example A | | | | | | |

The data in Tables 2-4 illustrate the benefits of the plasma deposited, silicon-containing layer in the FEC articles of the present invention. In general, the FEC articles of Examples 1-15 exhibited a combination of good initial interlayer adhesion and good stability after exposure to heated conditions. In comparison, the FEC articles of Comparative Example A exhibited significant reductions in stability after exposure to heated conditions. As such, the FEC articles of the present invention are suitable for use in a variety of applications where the FEC articles may be subjected to heat over extended periods of time.

The data in Tables 3 and 4 also illustrate that the interlayer adhesion of the FEC articles of the present invention is reduced when the silicon-containing layer is too thick. This is shown with the FEC articles of Examples 10 and 15. The FEC article of Example 10 was manufactured with a TMS flow rate of 180 sccm (no other gases present) and a exposure time of 8 seconds. Similarly, the FEC article of Example 15 was manufactured with a TMS flow rate of 180 sccm, a nitrogen flow rate of 170 sccm, and an exposure time of 20 seconds. As discussed above, the extent of the plasma deposition may depend on a variety of processing factors, such as the composition of the gas and the exposure time. If the gas contains an large concentration of TMS and the exposure time is significant, a greater amount of ions will deposit on the substrate, increasing the thickness of the silicon-containing layer. The FEC articles of Examples 10 and 15 show that relatively thick silicon-containing layers may reduce the interlayer adhesions of the FEC articles.

### Examples 16-23 and Comparative Examples B-M

Examples 16-23 are FEC articles of the present invention that were prepared pursuant to the Planar Electrode Manufacturing Method and the Circuitization Method, as discussed above, with the exceptions that the pressures, the line speeds, the RF power, the DC bias, and the amps of the plasma deposition were varied as shown in Table 5. The chamber was filled with TMS at a gas flow rate of 178 sccm and oxygen at a gas flow rate of 181 sccm. Table 5 provides the pressures, the IR heating temperatures, the line speeds, the RF power, the DC bias, and the amps used during plasma deposition for manufacturing the FEC articles of Examples 16-23.

TABLE 5

| | Pressure | IR Heating | Line Speed | RF Power | DC Bias | Amps |
|---|---|---|---|---|---|---|
| Example | (milliTorr) | (celcius) | (meters/min.) | (watts) | (volts) | (seconds) |
| Example 16 | 7.1 | 225 | 3.0 | 1000 | 1180 | 4.9 |
| Example 17 | 7.1 | 225 | 3.0 | 500 | 788 | 4.9 |
| Example 18 | 8.2 | 225 | 3.0 | 1000 | 1160 | 4.9 |
| Example 19 | 8.0 | 350 | 6.1 | 1000 | 1144 | 8.5 |
| Example 20 | 6.8 | 350 | 6.1 | 1000 | 1148 | 8.5 |
| Example 21 | 8.0 | 350 | 6.1 | 1500 | 1454 | 8.5 |
| Example 22 | 8.0 | 350 | 6.1 | 1000 | 1142 | 8.5 |
| Example 23 | 11.0 | 350 | 6.1 | 1000 | 1165 | 8.5 |

Comparative Examples D-O are FEC articles that were prepared pursuant to the Planar Electrode Manufacturing Method and the Circuitization Method, as discussed above, with the exceptions that the gas contained only argon (no TMS), and the pressures, the line speeds, the RF power, the DC bias, and the amps of the plasma deposition were varied as shown in Table 6. Table 6 provides argon flow rates, the pressures, the IR heating temperatures, the line speeds, the RF power, the DC bias, and the amps used during plasma deposition for manufacturing the FEC articles of Comparative Examples B-M.

TABLE 6

| | Argon | | | | | | |
|---|---|---|---|---|---|---|---|
| | Flow Rate | Pressure | IR Heating | Line Speed | RF Power | DC Bias | Amps |
| Comparative Example | (sccm) | (milliTorr) | (celcius) | (meters/min.) | (watts) | (volts) | (seconds) |
| Comparative Example B | 350 | 3.4 | 175 | 1.5 | 1000 | 1258 | 2.8 |
| Comparative Example C | 645 | 13.0 | 175 | 1.5 | 1000 | 1232 | 2.8 |
| Comparative Example D | 840 | 23.0 | 175 | 1.5 | 1000 | 1214 | 2.8 |
| Comparative Example E | 770 | 23.0 | 225 | 3.0 | 1000 | 1219 | 4.2 |
| Comparative Example F | 595 | 13.0 | 225 | 3.0 | 1000 | 1242 | 4.2 |
| Comparative Example G | 595 | 11.5 | 225 | 3.0 | 500 | 868 | 4.2 |
| Comparative Example H | 595 | 12.2 | 225 | 3.0 | 1500 | 1526 | 4.2 |
| Comparative Example I | 820 | 23.0 | 225 | 3.0 | 1000 | 1222 | 4.2 |
| Comparative Example J | 740 | 23.0 | 300 | 4.6 | 1000 | 1254 | 5.2 |
| Comparative Example K | 740 | 22.6 | 300 | 4.6 | 1500 | 1520 | 5.2 |
| Comparative Example L | 580 | 13.0 | 300 | 4.6 | 1000 | 1300 | 5.2 |
| Comparative Example M | 325 | 3.0 | 300 | 4.6 | 1000 | 1354 | 5.2 |

The FEC articles of Examples 16-23 and Comparative Examples B-M were tested pursuant to the Initial Peel Strength Testing, the 250° C., 1 hr Peel Strength Testing, and the Solder Reflow Peel Strength Testing. Table 7 provides the peel strength results for the FEC articles of Examples 16-23 and Comparative Examples B-M.

TABLE 7

| | Peel Strength | Peel Strength | Percent Peel | Percent Peel |
|---|---|---|---|---|
| | (initial) | (initial) | Retention | Retention |
| Example | (grams/cm) | (lbs./in.) | (solder flow) | (250° C., 1 hr.) |
| Example 16 | 793 | 4.44 | 70% | 82% |
| Example 17 | 895 | 5.01 | 75% | 74% |
| Example 18 | 784 | 4.39 | 71% | 84% |
| Example 19 | 1048 | 5.87 | 70% | 73% |
| Example 20 | 1096 | 6.14 | 72% | 74% |
| Example 21 | 1093 | 6.12 | 72% | 80% |
| Example 22 | 1105 | 6.19 | 72% | 72% |
| Example 23 | 1107 | 6.20 | 74% | 76% |
| Comparative | 1482 | 8.30 | 2% | 57% |
| Example B | | | | |
| Comparative | 1480 | 8.29 | 5% | 51% |
| Example C | | | | |
| Comparative | 1532 | 8.58 | 8% | 50% |
| Example D | | | | |
| Comparative | 1473 | 8.25 | 35% | 16% |
| Example E | | | | |
| Comparative | 1429 | 8.00 | 34% | 16% |
| Example F | | | | |
| Comparative | 1223 | 6.85 | 59% | 4% |
| Example G | | | | |
| Comparative | 1514 | 8.48 | 22% | 46% |
| Example H | | | | |
| Comparative | 1423 | 7.97 | 37% | 19% |
| Example I | | | | |
| Comparative | 1327 | 7.43 | 49% | 3% |
| Example J | | | | |
| Comparative | 1461 | 8.18 | 28% | 18% |
| Example K | | | | |
| Comparative | 1270 | 7.11 | 45% | 8% |
| Example L | | | | |
| Comparative | 1305 | 7.31 | 32% | 9% |
| Example M | | | | |

The data provided in Table 7 further illustrates that the FEC articles of Examples 16-23 exhibited a combination of good initial interlayer adhesion and good stability after exposure to heated conditions and solder reflow. In comparison, the FEC articles of Comparative Examples B-M exhibited significant reductions in stability after exposure to the heated conditions and the solder reflow oven. As such, the FEC articles of the present invention are suitable for use in a variety of applications where the FEC articles may be subjected to heat. Moreover, the FEC articles of the present invention also exhibit good stability during solder reflow, allowing the FEC articles of the present invention to be secured to circuit boards and the like without significant detrimental effects.

### Examples 24-44

Examples 24-44 are FEC articles of the present invention that were prepared pursuant to the Planar Electrode Manufacturing Method and the Circuitization Method, as discussed above, with the exceptions that the pressures, the exposure times, and the RF power were varied as shown in Table 8. The chamber was also filled with varying volumetric gas flow rate ratios of TMS/oxygen. The FEC articles of Examples 22-44 were manufactured and tested to determine what effect the altering of the process variables would have on the interlayer adhesions and stability. Table provides volumetric gas flow rate ratios of TMS/oxygen, the pressures, the exposure times, and the RF power used during plasma deposition for manufacturing the FEC articles of Examples 24-44.

TABLE 8

| | Volumetric Flow | | | |
|---|---|---|---|---|
| | Rate Ratio of | Pressure | Exposure Time | RF Power |
| Example | TMS/Oxygen | (milliTorr) | (seconds) | (watts) |
| Example 24 | 1.75 | 7 | 1.5 | 500 |
| Example 25 | 0.25 | 7 | 4.8 | 1500 |
| Example 26 | 1.75 | 7 | 1.5 | 1500 |
| Example 27 | 0.25 | 25 | 4.8 | 500 |
| Example 28 | 1.75 | 7 | 4.8 | 500 |
| Example 29 | 2.50 | 16 | 3.1 | 1000 |
| Example 30 | 1.00 | 16 | 6.4 | 1000 |
| Example 31 | 1.00 | 34 | 3.1 | 1000 |
| Example 32 | 0.25 | 25 | 1.5 | 500 |
| Example 33 | 1.75 | 25 | 1.5 | 500 |
| Example 34 | 1.75 | 25 | 1.5 | 1500 |
| Example 35 | 0.25 | 7 | 1.5 | 1500 |
| Example 36 | 0.25 | 25 | 4.8 | 1500 |
| Example 37 | 1.00 | 16 | 3.1 | 1000 |
| Example 38 | 1.00 | 16 | 3.1 | 2000 |
| Example 39 | 1.75 | 25 | 4.8 | 500 |
| Example 40 | 1.75 | 7 | 4.8 | 1500 |
| Example 41 | 0.25 | 7 | 4.8 | 500 |
| Example 42 | 1.75 | 25 | 4.8 | 1500 |
| Example 43 | 0.25 | 25 | 1.5 | 1500 |
| Example 44 | 0.25 | 7 | 1.5 | 500 |

The FEC articles of Examples 24-44 were tested pursuant to the Initial Peel Strength Testing, the 250° C., 1 hr Peel Strength Testing, and the 150° C., 200 hr Peel Strength Testing. Table 9 provides the peel strength results for the FEC articles of Examples 24-44.

TABLE 9

| | Peel Strength | Peel Strength | Peel Strength | Peel Strength | Peel Strength | Peel Strength |
|---|---|---|---|---|---|---|
| | (initial) | (initial) | (250° C., 1 hr.) | (250° C., 1 hr.) | (150° C., 200 hr.) | (150° C., 200 hr.) |
| Example | (grams/cm) | (lbs./in.) | (grams/cm) | (lbs./in.) | (grams/cm) | (lbs./in.) |
| Example 24 | 636 | 3.56 | 531 | 2.97 | 453 | 2.53 |
| Example 25 | 659 | 3.69 | 531 | 2.98 | 517 | 2.90 |
| Example 26 | 154 | 0.86 | 201 | 1.13 | 275 | 1.54 |
| Example 27 | 847 | 4.75 | 458 | 2.57 | 279 | 1.56 |
| Example 28 | 375 | 2.10 | 539 | 3.02 | 386 | 2.16 |
| Example 29 | 192 | 1.07 | 471 | 2.64 | 328 | 1.84 |
| Example 30 | 163 | 0.91 | 244 | 1.37 | 313 | 1.76 |
| Example 31 | 676 | 3.78 | 324 | 1.81 | 551 | 3.09 |
| Example 32 | 829 | 4.64 | 96 | 0.54 | 112 | 0.63 |
| Example 33 | 577 | 3.23 | 165 | 0.92 | 429 | 2.40 |
| Example 34 | 766 | 4.29 | 376 | 2.11 | 529 | 2.96 |
| Example 35 | 985 | 5.51 | 524 | 2.93 | 437 | 2.45 |
| Example 36 | 562 | 3.15 | 345 | 1.93 | 192 | 1.08 |
| Example 37 | 632 | 3.54 | 324 | 1.81 | 553 | 3.10 |
| Example 38 | 110 | 0.61 | 645 | 3.61 | 516 | 2.89 |
| Example 39 | 679 | 3.80 | 371 | 2.08 | 545 | 3.05 |
| Example 40 | 335 | 1.88 | 236 | 1.32 | 251 | 1.41 |
| Example 41 | 724 | 4.05 | 547 | 3.06 | 532 | 2.98 |
| Example 42 | 246 | 1.38 | 253 | 1.42 | 292 | 1.64 |
| Example 43 | 955 | 5.35 | 193 | 1.08 | 192 | 1.08 |
| Example 44 | 593 | 3.32 | 246 | 1.38 | 233 | 1.31 |

The data provided in Table 9 illustrates that several combinations of process variables provide a combination of good initial interlayer adhesion and good stability after exposure to heated conditions (e.g., the FEC articles of Examples 24, 25, 31, 34, 35, 37, 39, and 41). This demonstrates that the process window for obtaining a silicon-containing layer that provides good initial interlayer adhesion and good stability after exposure to heated conditions, is relatively wide.

### Examples 45-56

Examples 45-56 are FEC articles that were prepared pursuant to the Planar Electrode Manufacturing Method (but not the Circuitization Method), as discussed above, with the exceptions that the pressures and the RF power were varied as shown in Table 10, and the exposure time for each FEC article was 30 seconds. The FEC articles of Examples 45-56 were manufactured and tested to help examine the actual concentrations of oxygen, carbon, and silicon present in the silicon-containing layers. The 30 second exposure time was used to obtain sufficiently thick layers that could be analyzed. Table 10 provides gas flow rates of TMS and oxygen, the pressures, and the RF power used during plasma deposition for manufacturing the FEC articles of Examples 45-56. Table 11 provides the concentrations of oxygen, carbon, and silicon present in the silicon-containing layers of the FEC articles of Examples 45-56, as analyzed with an Electron Spectroscopy for Chemical Analysis (ESCA).

TABLE 10

| | TMS Flow | Oxygen Flow | Volumetric Flow Rate | Pressure | RF Power |
|---|---|---|---|---|---|
| Example | Rate (sccm) | Rate (sccm) | Ratio of TMS/Oxygen | (milliTorr) | (watts) |
| Example 45 | 255 | 145 | 1.75 | 7 | 500 |
| Example 46 | 80 | 320 | 0.25 | 7 | 1500 |
| Example 47 | 255 | 145 | 1.75 | 7 | 1500 |
| Example 48 | 50 | 200 | 0.25 | 25 | 500 |
| Example 49 | 198 | 80 | 2.50 | 16 | 1000 |
| Example 50 | 100 | 100 | 1.00 | 16 | 1000 |
| Example 51 | 200 | 200 | 1.00 | 34 | 1000 |
| Example 52 | 255 | 145 | 1.75 | 25 | 500 |
| Example 53 | 255 | 145 | 1.75 | 25 | 1500 |
| Example 54 | 50 | 200 | 0.25 | 25 | 1500 |
| Example 55 | 100 | 100 | 1.00 | 16 | 2000 |
| Example 56 | 80 | 320 | 0.25 | 7 | 500 |

TABLE 11

| | | | Atomic | Ratio of |
|---|---|---|---|---|
| | Atomic percent | Atomic percent | percent | Oxygen to |
| Example | Oxygen | Carbon | Silicon | Silicon |
| Example 45 | 32 | 42 | 26 | 1.23 |
| Example 46 | 41 | 34 | 24 | 1.71 |
| Example 47 | 35 | 39 | 26 | 1.35 |
| Example 48 | 43 | 29 | 28 | 1.54 |
| Example 49 | 31 | 42 | 26 | 1.19 |
| Example 50 | 37 | 38 | 25 | 1.48 |
| Example 51 | 40 | 33 | 27 | 1.48 |
| Example 52 | 33 | 44 | 23 | 1.43 |
| Example 53 | 34 | 45 | 21 | 1.62 |
| Example 54 | 48 | 28 | 22 | 2.18 |
| Example 55 | 36 | 46 | 19 | 1.89 |
| Example 56 | 42 | 33 | 25 | 1.68 |

The data in Table 11 illustrates the effects of the processing variables on the concentrations of the oxygen, carbon, and silicon present in the silicon-containing layers of the FEC articles of Examples 45-56. In particular, the data illustrates that the oxygen/TMS ratio in a silicon-containing layer of an FEC article of the present invention may be increased by increasing the RF power, by increasing the chamber pressure, and/or decreasing the TMS/oxygen volumetric flow rate ratio.

### Examples 57-59 and Comparative Examples N and O

Examples 57-59 are FEC articles of the present invention that were prepared pursuant to the Planar Electrode Manufacturing Method and the Circuitization Method, as discussed above. The FEC article of Example 57 was manufactured with a TMS flow rate of 180 sccm and an argon flow rate of 170 sccm. The FEC article of Example 58 was manufactured with a TMS flow rate of 180 sccm and an oxygen flow rate of 170 sccm. The FEC article of Example 59 was manufactured with a TMS flow rate of 80 sccm and an oxygen flow rate of 320 sccm.

The FEC article of Comparative Example N was a polyimide substrate that was not subject to plasma deposition or circuitization, and provides a baseline for comparing how the insulation resistances are affected by plasma deposition. The FEC article of Comparative Example O was prepared pursuant to the Planar Electrode Manufacturing Method and the Circuitization Method, as discussed above, with an argon flow rate of 170 sccm (no TMS).

The FEC articles of Examples 57 and 58 and Comparative Examples N and O were tested pursuant to the Insulation Resistance Testing. Table 12 provides the insulation resistance results for the FEC articles of Examples 57 and 58 and Comparative Examples N and O.

TABLE 12

| Example | Sheet Resistance (ohms/square) |
|---|---|
| Example 57 | 5.00 × 10¹² |
| Example 57 | 4.55 × 10¹²* |
| Example 58 | 2.50 × 10¹⁵ |
| Comparative Example N | 2.50 × 10¹⁶ |
| Comparative Example O | 1.00 × 10¹¹ |

*Sheet Resistance measured at 85° C. and 85% humidity.

The data in Table 12 illustrates the benefits of the plasma-deposited, silicon-containing layer with respect to insulation resistance. As discussed above, the polyimide substrate of Comparative Example N provides an insulation resistance baseline. As shown in Table 12, the FEC articles of Examples 57 and 58 retain greater levels of insulation resistance compared to Comparative Example O. It is believed that the argon plasma treatment, without TMS may have graphitized the surface of the polyimide substrate of Comparative Example O.

Additionally, the data in Table 12 shows that the FEC article of Example 58, which used TMS and oxygen, did not substantially lose any insulation resistance relative to the polyimide substrate of Comparative Example N. Accordingly, in addition to exhibiting good interlayer adhesion and stability, the FEC articles of the present invention also exhibit good insulation resistance. This reduces the chances of having leakage currents existing between the traces.

The FEC article of Example 59 was divided into five separate squares (Examples 59a-59e), which were retained in an oven set at a temperature of 85° C. and a relative humidity of 85%. The FEC articles were tested pursuant to the Insulation Resistance Testing several times over 10 days while retained in the oven. Table 13 provides the sheet resistance results (ohms/square) for the FEC articles of Examples 59a-59e.

TABLE 13

| Example | Day 2 | Day 3 | Day 6 | Day 8 | Day 9 | Day 10 |
|---|---|---|---|---|---|---|
| Example 59a | 7.67 × 10¹³ | 1.68 × 10¹⁴ | 3.45 × 10¹⁴ | 4.06 × 10¹⁴ | 3.63 × 10¹⁴ | 3.63 × 10¹⁴ |
| Example 59b | 1.68 × 10¹⁴ | 1.92 × 10¹⁴ | 2.23 × 10¹⁴ | 3.29 × 10¹⁴ | 3.00 × 10¹⁴ | 3.63 × 10¹⁴ |
| Example 59c | 2.76 × 10¹⁵ | 3.83 × 10¹⁵ | 4.93 × 10¹⁵ | 6.27 × 10¹⁵ | 4.93 × 10¹⁵ | 1.15 × 10¹⁵ |
| Example 59d | 1.64 × 10¹⁴ | 2.65 × 10¹⁴ | 4.93 × 10¹⁴ | 6.90 × 10¹⁴ | 6.90 × 10¹⁴ | 7.67 × 10¹⁴ |
| Example 59e | 1.86 × 10¹⁴ | 3.00 × 10¹⁴ | 3.29 × 10¹⁴ | 3.83 × 10¹⁴ | 4.60 × 10¹⁴ | 4.60 × 10¹⁴ |

The data in Table 13 illustrates that the sheet resistances of the FEC articles of present invention plasma deposited with TMS and oxygen are good even under high humidity and temperature conditions over a period of ten days. This example further illustrates the utility of the FEC articles of the invention, which exhibit good peel strength, stability and also insulation resistance, even over extended periods of time.

Although the present invention has been described with reference to preferred embodiments, workers skilled in the art will recognize that changes may be made in form and detail without departing from the spirit and scope of the invention.

1. An electronic-circuit article comprising:
a substrate;
a plasma deposited layer disposed on the substrate, wherein the plasma deposited layer comprises at least about 10.0 atomic percent silicon; and
a patterned conductive layer disposed above the plasma deposited layer.

2. The electronic-circuit article of claim 1, wherein the plasma deposited layer comprises at least about 20.0 atomic percent silicon

3. The electronic-circuit article of claim 1, wherein the plasma deposited layer further comprises at least about 15.0 atomic percent oxygen, based on the total weight of the plasma deposited layer.

4. The electronic-circuit article of claim 3, wherein the plasma deposited layer further comprises at least about 25.0 atomic percent oxygen

5. The electronic-circuit article of claim 1, wherein the plasma deposited layer has a thickness ranging from about 0.5 nanometers to about 10.0 nanometers.

6. The electronic-circuit article of claim 5, wherein the thickness is as low as about 1.0 nanometer and is as high as about 5.0 nanometers.

7. The electronic-circuit article of claim 1, wherein the plasma deposited layer is derived from a gas comprising at least about 50.0 atomic percent of an organosilicon compound.

8. The electronic-circuit article of claim 7, wherein the organosilicon compound comprises tetramethylsilane.

9. The electronic-circuit article of claim 7, wherein the gas further comprises one or more of oxygen, argon, nitrogen, ammonia, and hydrogen.

10. The electronic-circuit article of claim 1, further comprising a metallic tie layer disposed between the plasma deposited layer and the patterned conductive layer.

11. An electronic-circuit article comprising:
a polyimide substrate;
a plasma deposited layer disposed on the polyimide substrate, wherein the plasma deposited layer is derived from a gas comprising at least about 50.0 atomic percent of an organosilicon compound;
and a patterned conductive layer disposed above the plasma deposited layer.

12. The electronic-circuit article of claim 11, wherein the organosilicon compound comprises tetramethylsilane.

13. The electronic-circuit article of claim 11, wherein the gas further comprises one or more of oxygen, argon, nitrogen, ammonia, and hydrogen.

14. The electronic-circuit article of claim 11, wherein the plasma deposited layer has a thickness ranging from about 0.5 nanometers to about 10.0 nanometers.

15. The electronic-circuit article of claim 11, wherein the thickness is as low as about 1.0 nanometer and is as high as about 5.0 nanometers.

16. A method of forming an electronic-circuit article, the method comprising:
forming a silicon-containing layer on a substrate by plasma deposition;
depositing a layer of conductive material above the silicon-containing layer; and
patterning the layer of conductive material.

17. The method of claim 16, wherein forming the silicon-containing comprises ionizing a gas comprising an organosilicon compound.

18. The method of claim 17, wherein the organosilicon compound comprises tetramethylsilane.

19. The method of claim 17, wherein the organosilicon compound constitutes at least about 50.0 atomic percent of the gas, based on the total atomic of the gas.

20. The method of claim 17, wherein the gas further comprises one or more of oxygen, argon, nitrogen, ammonia, and hydrogen.

21. The method of claim 16, wherein patterning the layer of conductive material comprises etching the layer of conductive material by photolithography.

22. The method of claim 16 further comprising depositing a metallic tie layer on the silicon-containing layer.

23. The method of claim 16 further comprising exposing the substrate is to plasma for an exposure time effective to provide the silicon-containing layer with a thickness ranging from about 0.5 nanometers to about 10.0 nanometers.

24. The method of claim 23 further comprising exposing the substrate is to plasma for an exposure time effective to provide the silicon-containing layer with a thickness ranging from about 1.0 nanometers to about 5.0 nanometers.
